(19) United States
(12) Patent Application Publication
(10) Pub. No.: US 2026/0095532 A1
(43) Pub. Date: Apr. 2, 2026

(54) POWER SUPPLY MANAGEMENT CIRCUIT

(71) Applicant: Toshiba Tec Kabushiki Kaisha, Tokyo (JP)

(72) Inventor: Zhichao ZHENG, Sunto Shizuoka (JP)

(21) Appl. No.: 19/329,041

(22) Filed: Sep. 15, 2025

(30) Foreign Application Priority Data
Oct. 1, 2024 (JP) 2024-172639

(51) Int. Cl. H04N 1/00; H03K 17/296

(52) U.S. Cl. CPC H04N 1/00888; H03K 17/296; H04N 1/00899; H04N 1/00904

(57) ABSTRACT

According to an embodiment, a power supply management circuit of a printer includes a first switch, a second switch, a logic circuit, a power supply management integrated circuit, and a control circuit. When the first switch is switched, the logic circuit closes the second switch, and the power supply management integrated circuit starts sequence control of power supply startup in accordance with the closing. Further, when the first switch is long-pressed, the power supply management integrated circuit starts sequence control of power supply shutdown, and the control circuit causes the logic circuit to output a control signal to open the second switch.

### CROSS-REFERENCE TO RELATED APPLICATIONS

This application is based upon and claims the benefit of priority from the prior Japanese Patent Application No. 2024-172639, filed on Oct. 1, 2024, the entire contents of which are incorporated herein by reference.

### FIELD

Embodiments described herein generally relate to a power supply management circuit mounted on a printer that performs printing on label paper or receipt paper.

### BACKGROUND

In a printer that performs printing on label paper or receipt paper, it is necessary to generate a plurality of power supply voltages using a plurality of step-down circuits in the internal circuitry.

To address such a situation, it is envisioned that in the future a printer will be equipped with a power supply management integrated circuit (IC) that manages the generation of a plurality of power supply voltages and the stop of the generation. In such a case, on/off control of the power supply management IC will be required in addition to the conventional on/off control of the printer.

### BRIEF DESCRIPTION OF THE DRAWINGS

FIG. 1 is a block diagram showing an example of a configuration of a power supply management circuit according to an embodiment.

FIG. 2 is a flowchart showing a flow of sequence control of power supply startup and power supply shutdown performed by the power supply management circuit according to the embodiment.

FIG. 3 is a time chart of the sequence control of power supply startup and power supply shutdown performed by the power supply management circuit according to the embodiment.

### DETAILED DESCRIPTION

According to an embodiment, a power supply management circuit of a printer includes a first switch, a second switch, a logic circuit, a power supply management integrated circuit, and a control circuit. The first switch is configured to be switched by a user. The second switch is configured to generate a first voltage and stop generating the first voltage in accordance with opening/closing of the second switch. The logic circuit is configured to control the opening/closing of the second switch. The power supply management integrated circuit is configured to perform sequence control of power supply startup and power supply shutdown. The control circuit is configured to control an output of the logic circuit. In addition, when the first switch is switched, the logic circuit closes the second switch, and the power supply management integrated circuit starts the sequence control of power supply startup in accordance with the closing of the second switch. Further, when the first switch is long-pressed, the power supply management integrated circuit starts the sequence control of power supply shutdown, and the control circuit causes the logic circuit to output a control signal to open the second switch.

Hereinafter, an embodiment will be described with reference to the drawings. In the drawings, the same reference symbols denote the same or similar portions. A power supply management circuit according to this embodiment is mounted on a printer that performs printing on label paper or receipt paper. A printer equipped with the power supply management circuit according to this embodiment houses a roll of label paper or receipt paper, which is rolled into a roll, inside a casing, prints characters, codes, and the like on the label paper or receipt paper drawn from the roll and conveyed, and cuts the paper into labels or receipts.

In addition, the printer includes a power supply circuit that converts alternating-current (AC) power supplied from a commercial power supply into direct-current (DC) power and supplies the converted DC power to the power supply management circuit according to this embodiment. Various devices such as a scanner and a card reader are connected to the printer.

### Configuration Example of Power Supply Management Circuit

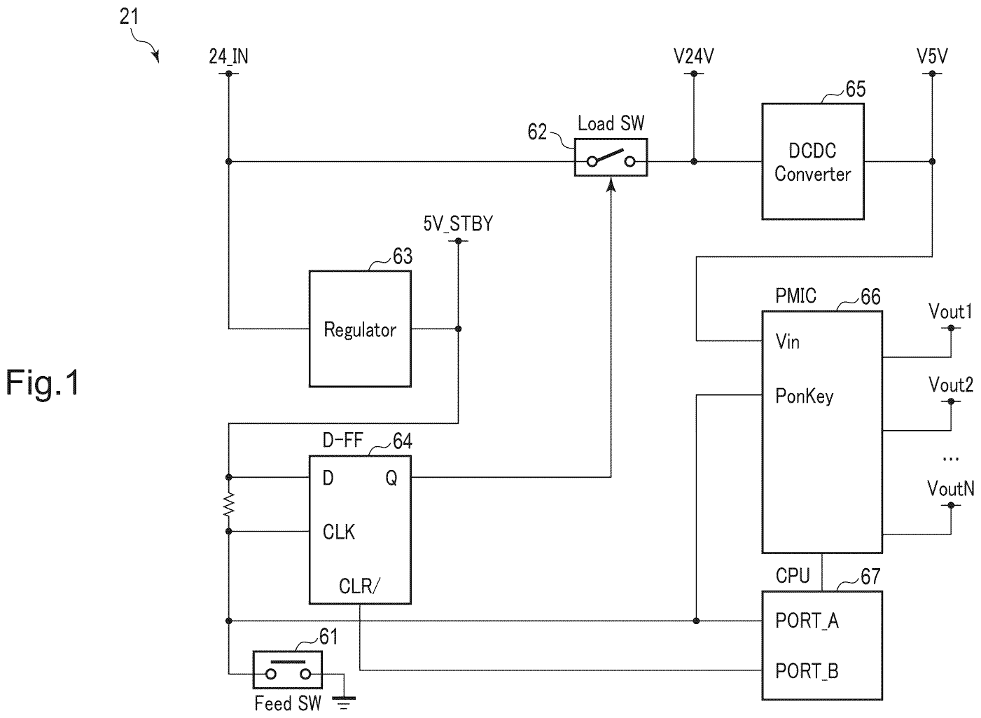

A power supply management circuit 21 according to the embodiment will be described with reference to FIG. 1. FIG. 1 is a block diagram showing an example of a configuration of the power supply management circuit 21 according to the embodiment.

The power supply management circuit 21 performs power supply management of each part of the printer 10. For example, the power supply management circuit 21 is supplied with DC power from a power circuit 20, and generates and stops generating a power supply voltage of a voltage level suitable for the internal operation of the printer 10 and a power supply voltage of a voltage level suitable for various devices connected to the printer 10. Hereinafter, for convenience, the generation of a power supply voltage will be also referred to as power supply startup, and the stop of generation of a power supply voltage will be also referred to as power supply shutdown. The power supply management circuit 21 also performs sequence control to generate and stop generating a power supply voltage (power supply startup and power supply shutdown) for each block of the internal circuitry of the printer 10.

The power supply management circuit 21 includes a feed switch 61 (Feed SW), a load switch 62 (Load SW), a regulator 63 (Regulator), a D flip-flop 64 (D-FF), a DCDC converter 65 (DCDC Converter), a power supply management integrated circuit (IC) 66 (PMIC: power management IC), and a CPU 67.

The feed switch 61 is switched by a user. The feed switch 61 is a switch for driving a feed motor for conveying label paper or receipt paper. The feed switch 61 generates switch signals as binary signals of “H” and “L” in response to the switch operation. The switch signals generated by the feed switch 61 are input to the D flip-flop 64, the power supply management IC 66, and the CPU 67.

The feed switch 61 is a push button switch and includes a button that can be pressed. For example, the feed switch 61 is closed when the button is pressed, and is opened when the pressing of the button is released. The feed switch 61 generates “L” while the button is pressed, and generates “H” while the pressing of the button is released.

In the following, the pressing the button of the feed switch 61 and the release of the pressing the button of the feed switch 61 will be simply referred to as pressing and release of pressing, respectively. The switch operation includes the pressing and the release of pressing, which is subsequent to the pressing. In addition, the switch operation includes pressing for less than a predetermined time, short pressing including release of pressing subsequent to the pressing for less than a predetermined time, pressing for a predetermined time or more, and long pressing including release of pressing subsequent to the pressing for a predetermined time or more. The terms “less than” and “or more/equal to or more than” are not strictly defined and may be “equal to or less than” and “more than”, respectively.

The load switch 62 is supplied with a high voltage (24_IN) of 24 V from the power circuit 20. In other words, an input terminal of the load switch 62 is connected to the supply source (power circuit 20) of the high voltage (24_IN). The load switch 62 generates and stops generating the high voltage (V24V), which is the power supply voltage used inside the printer 10, on the output terminal side in accordance with the opening/closing of the load switch 62. The load switch 62 generates the high voltage (V24V) on the output terminal side when the load switch 62 is closed, and stops generating the high voltage (V24V) on the output terminal side when the load switch 62 is opened.

The opening/closing of the load switch 62 is controlled by a control signal as a binary signal generated by the D flip-flop 64. For example, the load switch 62 is closed when receiving an input of a control signal of “H” from the D flip-flop 64, and is opened when receiving an input of a control signal of “L” from the D flip-flop 64. In other words, the load switch 62 is closed while receiving an input of a control signal of “H” and is opened while receiving an input of a control signal of “L”.

The regulator 63 is supplied with a high voltage (24_IN) of 24 V and constantly generates a voltage of 5 V. The voltage generated by the regulator 63 is used, for one thing, as a standby voltage (5V_STBY), which is the voltage required to maintain internal circuits and functions when the printer 10 is in a standby mode or sleep mode. The voltage generated by the regulator 63 (output signal) is also input to the D flip-flop 64 as a binary signal of “H”.

The D flip-flop 64 is a logic circuit that holds one-bit information. The one-bit information is a control signal as a binary signal that controls the opening/closing of the load switch 62.

The D flip-flop 64 includes three input terminals of a D terminal, a CLK terminal, and a clear (CLR/) terminal, and one output terminal of a Q terminal.

The D terminal of the D flip-flop 64 receives an input of the voltage generated by the regulator 63 (output signal). The input of the D terminal is constantly the binary signal of “H”.

The CLK terminal of the D flip-flop 64 receives an input of the switch signal of the feed switch 61. As described above, the feed switch 61 generates “L” while being pressed, and generates “H” while the pressing is released. Specifically, the CLK terminal is connected to the feed switch 61 and also to the output terminal of the regulator 63 via a resistor. As a result, the input of the CLK terminal is switched from “H” to “L” when the feed switch 61 is pressed, and switched from “L” to “H” when the pressing of the feed switch 61 is released.

The clear terminal of the D flip-flop 64 receives an input of a clear signal from the CPU 67. In the embodiment, as an example, the clear signal is temporarily changed to the binary signal of “L” when the supply of the power supply voltage from the power supply management circuit 21 to each part of the printer 10 is stopped, and is the binary signal of “H” in the other cases.

The Q terminal of the D flip-flop 64 outputs the control signal for opening/closing the load switch 62. The control signal for opening/closing the load switch 62 is either the binary signal of “H” or “L”.

The D flip-flop 64 controls opening/closing of the load switch 62. For this purpose, the D flip-flop 64 outputs the control signal for opening/closing the load switch 62 from the Q terminal to the load switch 62. The D flip-flop 64 outputs “L” from the Q terminal in the initial state. When the feed switch 61 is switched from this state, the D flip-flop 64 switches the output of the Q terminal from “L” to “H”. Such switch operation includes the pressing and the release of pressing subsequent to the pressing. In other words, when the feed switch 61 is pressed and then the pressing is released, the D flip-flop 64 switches the output of the Q terminal from “L” to “H”. Specifically, the D flip-flop 64 holds the input of “H” to the D terminal at the timing at which the input to the CLK terminal is switched from “L” to “H”, and continues to output “H” from the Q terminal.

In the initial state, the D flip-flop 64 receives an input of “H” in the clear terminal. When the D flip-flop 64 receives an input of “L” in the clear terminal while outputting “H” from the Q terminal, the D flip-flop 64 switches the output of the Q terminal from “H” to “L”. The D flip-flop 64 maintains “L” for the output of the Q terminal while “L” is continued to be input to the clear terminal. After that, upon reception of an input of “H” to the clear terminal, the D flip-flop 64 performs operation according to the input of the CLK terminal.

The DCDC converter 65 is supplied with a high voltage (V24V) generated by the load switch 62 and generates a voltage of 5 V. The voltage generated by the DCDC converter 65 is input to the power supply management IC 66. The voltage generated by the DCDC converter 65 may also be used as a power supply voltage (V5V) for blocks of the internal circuitry that does not require sequence control.

The power supply management IC 66 is an integrated circuit that performs sequence control to generate and stop generating a power supply voltage. The power supply management IC 66 includes two input terminals of a Vin terminal and a power-on key (PonKey) terminal.

The Vin terminal of the power supply management IC 66 receives an input of the voltage generated by the DCDC converter 65. The input voltage (Vin) of the power supply management IC 66 is an operation voltage for operating the power supply management IC 66.

The power-on key terminal of the power supply management IC 66 receives an input of the switch signal of the feed switch 61. As described above, the feed switch 61 generates “L” when it is pressed, and generates “H” when the pressing is released.

The power supply management IC 66 is controlled to be activated by the switch signal of the feed switch 61, which is input to the power-on key terminal. When the power-on key terminal receives an input of “H”, the power supply management IC 66 enters a startup state.

The power supply management IC 66 can operate in two modes: an auto turn-on mode; and a power key turn-on mode. In the embodiment, the power supply management IC 66 is operated in the auto turn-on mode.

In the auto turn-on mode, the power supply management IC 66 generates and stops generating a plurality of low voltages (Vout1, Vout2, . . . , VoutN) in accordance with the inputs of the Vin terminal and the power-on key terminal. In addition, the power supply management IC 66 performs sequence control to generate and stop generating a plurality of low voltages (Vout1, Vout2, . . . , VoutN). The plurality of low voltages (Vout1, Vout2, . . . , VoutN) are power supply voltages respectively used by various devices connected to the printer 10.

In other words, the power supply management IC 66 performs the power supply startup and power supply shutdown at a plurality of low voltage (Vout1, Vout2, . . . , VoutN) levels and the sequence control of the power supply startup and power supply shutdown, in accordance with the inputs of the Vin terminal and the power-on key terminal.

For example, when the power supply management IC 66 is in the startup state in which “H” is input to the power-on key terminal, and when the Vin terminal receives an input of the operation voltage (Vin), the power supply management IC 66 starts the sequence control of power supply startup, and outputs a plurality of low voltages (Vout1, Vout2, . . . , VoutN) at respective timings. In other words, the power supply management IC 66 switches the outputs of the plurality of low voltages (Vout1, Vout2, . . . , VoutN) from “L” to “H” at the respective timings.

Subsequently, when the power supply management IC 66 receives an input of “L” to the power-on key terminal while outputting low voltages (Vout1, Vout2, . . . , VoutN), the power supply management IC 66 starts the sequence control of power supply shutdown and stops outputting the plurality of low voltages (Vout1, Vout2, . . . , VoutN) at the respective timings. In other words, the power supply management IC 66 switches the outputs of the plurality of low voltages (Vout1, Vout2, . . . , VoutN) from “H” to “L” at the respective timings.

In the sequence control of power supply startup, the power supply management IC 66 starts outputting a plurality of low voltages (Vout1, Vout2, . . . , VoutN) in a predetermined order. Meanwhile, in the sequence control of power supply shutdown, the power supply management IC 66 stops outputting a plurality of low voltages (Vout1, Vout2, . . . , VoutN) in reverse order from the startup.

When the feed switch 61 is long-pressed while a plurality of low voltages (Vout1, Vout2, . . . , VoutN) are output, the power supply management IC 66 starts the sequence control of power supply shutdown. The long pressing includes the pressing continued for a predetermined time or more, and the release of pressing subsequent to the former pressing. Here, the execution of the long pressing of the feed switch 61 is assumed to have been accomplished with the pressing continued for a predetermined time or more, without having to wait for the release of pressing subsequent to the former pressing.

Thus, when the Vin terminal receives an input of the operation voltage, and when the power-on key terminal receives an input of “L” while the low voltages (Vout1, Vout2, . . . , VoutN) are output, the power supply management IC 66 starts measuring the duration of the input of “L” to the power-on key terminal, that is, the duration of the pressing of the feed switch 61.

When the duration of the pressing of the feed switch 61 reaches a predetermined time, the power supply management IC 66 determines that the long pressing of the feed switch 61 has been executed, and starts the sequence control of power supply shutdown, and stops outputting the low voltages (Vout1, Vout2, . . . , VoutN) at the respective timings. When the sequence control of power supply shutdown is completed, the power supply management IC 66 stops the operation.

If the duration of the pressing of the feed switch 61 does not reach a predetermined time, the power supply management IC 66 determines that the long pressing of the feed switch 61 has not been executed due to the situation in which the pressing of the feed switch 61 is released before the predetermined time elapses, and continues to output the low voltages (Vout1, Vout2, . . . , VoutN).

The CPU 67 is a control circuit that controls the output of the D flip-flop 64. The CPU 67 includes an input port of an A port (PORT_A) and an output port of a B port (PORT_B).

The A port of the CPU 67 receives an input of the switch signal of the feed switch 61. As described above, the feed switch 61 generates “L” while being pressing, and generates “H” while the pressing is released.

The B port of the CPU 67 outputs the clear signal to the clear terminal of the D flip-flop 64. As described above, the clear signal is temporarily changed to the binary signal of “L” when the supply of the power supply voltage from the power supply management circuit 21 to each part of the printer 10 is stopped, and is the binary signal of “H” in the other cases.

The CPU 67 outputs the clear signal from the B port to the clear terminal of the D flip-flop 64 in accordance with the input of the switch signal of the feed switch 61 to the A port. The CPU 67 outputs “H” in the initial state.

When the feed switch 61 is long-pressed, the CPU 67 temporarily switches the clear signal from “H” to “L”, and then returns the clear signal from “L” to “H”.

In one example, the CPU 67 outputs the clear signal in response to the input of the switch signal of the feed switch 61. In the initial state, the input to the A port of the CPU 67 is the switch signal of “H”, and the CPU 67 outputs the clear signal of “H”.

When the feed switch 61 is pressed and the switch signal input to the A port of the CPU 67 is switched from “L” to “H”, the CPU 67 starts measuring the duration of the pressing of the feed switch 61.

When the pressing of the feed switch 61 is released and the switch signal input to the A port of the CPU 67 is switched from “H” to “L”, the CPU 67 terminates the measurement of the duration of the pressing of the feed switch 61.

Next, the CPU 67 compares the duration of the pressing of the feed switch 61 with a predetermined time. If the duration of the pressing of the feed switch 61 is equal to or more than a predetermined time, the CPU 67 temporarily outputs the clear signal of “L”, and then outputs the clear signal of “H” again. Conversely, if the duration of the pressing of the feed switch 61 is less than the predetermined time, the CPU 67 continues to output the clear signal of “H”.

In another example, after the completion of the sequence control of power supply shutdown by the power supply management IC 66, which has been started by long-pressing the feed switch 61, the CPU 67 temporarily switches the clear signal from “H” to “L” and then returns the clear signal from “L” to “H”.

In this case, if the duration of the pressing of the feed switch 61 is equal to or more than a time obtained by adding a time required for the sequence control of power supply shutdown to the predetermined time, the CPU 67 temporarily outputs the clear signal of “L”. If the duration of the pressing of the feed switch 61 is less than the time obtained by adding a time required for the sequence control of power supply shutdown to the predetermined time, the CPU 67 temporarily outputs a clear signal of “L” after the shortage time has elapsed.

Alternatively, the power supply management IC 66 notifies the CPU 67 of the completion of the sequence control of power supply shutdown before stopping the operation. The CPU 67 temporarily outputs the clear signal of “L” when receiving the notification on the completion of the sequence control of power supply shutdown from the power supply management IC 66.

### Operation Example of Power Supply Management Circuit

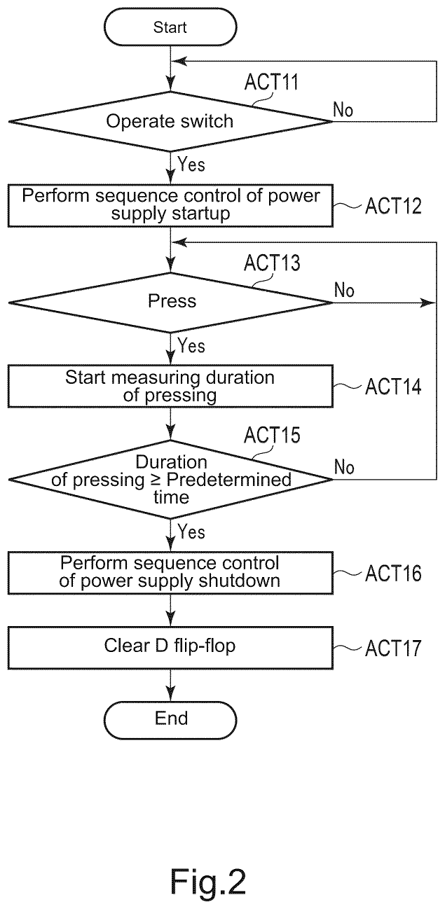

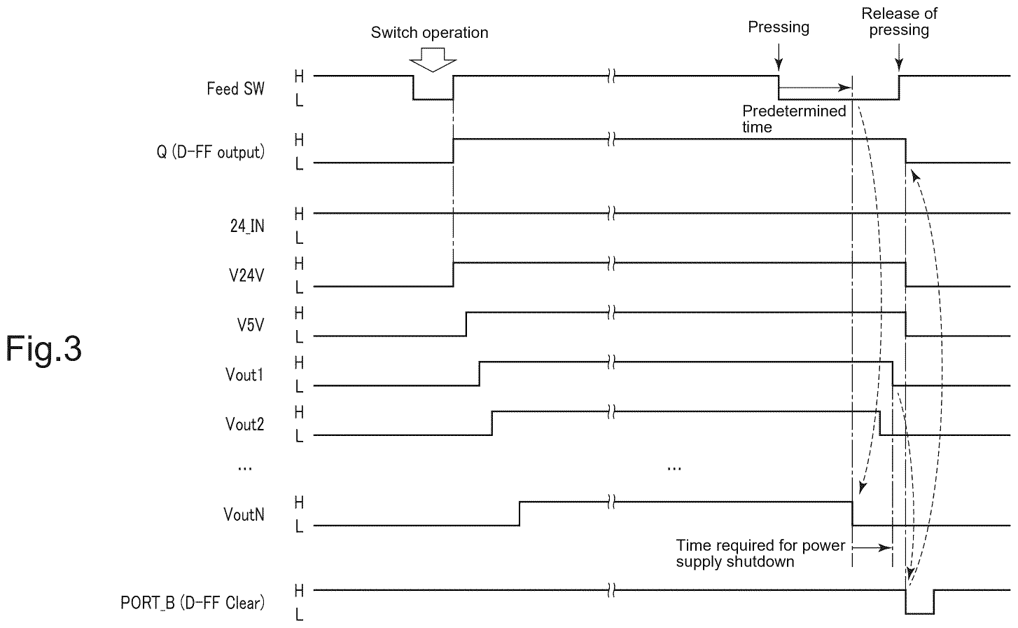

Next, an operation example of the power supply management circuit 21 according to the embodiment will be described with reference to FIGS. 2 and 3. FIG. 2 is a flowchart showing a flow of the sequence control of power supply startup and power supply shutdown performed by the power supply management circuit 21 according to the embodiment. FIG. 3 is a time chart of the sequence control of power supply startup and power supply shutdown performed by the power supply management circuit 21 according to the embodiment.

The operation of the power supply management circuit 21 to be described below is an operation from the state of waiting for the turn-on of the main power supply of the printer 10 to the turn-off of the main power supply.

In the state of waiting for the turn-on of the main power supply of the printer 10, the load switch 62 and the regulator 63 of the power supply management circuit 21 are supplied with a high voltage (24_IN) of 24 V. The regulator 63 generates a voltage of 5 V. The voltage generated by the regulator 63 is used, for one thing, as a standby voltage (5V_STBY) of the printer 10. The voltage generated by the regulator 63 (output signal) is also input to the D terminal of the D flip-flop 64 and input to the CLK terminal of the D flip-flop 64 via the resistor.

For example, the standby voltage (5V_STBY) generated by the regulator 63 is supplied to a main controller 19. In addition, the standby voltage (5V_STBY) is supplied to the D flip-flop 64, the DCDC converter 65, the power supply management IC 66, the CPU 67, and the like.

Note that when the printer 10 is waiting for the initial turn-on of the main power supply, that is, when a power supply cable of the printer 10 is plugged into an outlet for the first time, the Q output of the D flip-flop 64 is set to “L” by the initialization processing. For example, the CPU 67 temporarily outputs a clear signal of “L” from the B port to the clear terminal of the D flip-flop 64. The D flip-flop 64 continuously outputs “L” from the Q terminal upon receiving an input of the clear signal to the clear terminal.

In addition, as will be described later, even when the main power supply is disconnected, the CPU 67 temporarily outputs the clear signal of “L” to the D flip-flop 64, and the D flip-flop 64 continuously outputs “L” from the Q terminal upon receiving an input of the clear signal.

In ACT11, the power supply management circuit 21 is in a state of waiting for the turn-on of the main power supply of the printer 10, and is waiting for the execution of the switch operation on the feed switch 61 to turn on the main power supply. The switch operation includes the pressing of the feed switch 61 and the subsequent release of the pressing of the feed switch 61. The switch operation may be short pressing or long pressing.

Until the switch operation on the feed switch 61 is executed (during No in ACT 11), the power supply management circuit 21 continues to wait for the execution of the switch operation on the feed switch 61.

When the switch operation on the feed switch 61 is executed (Yes in ACT11), the power supply management IC 66 receives an input of a switch signal of “H” to the power-on key terminal in the release of pressing for the switch operation on the feed switch 61, and enters a startup state.

In addition, the D flip-flop 64 receives an input of a switch signal of “L” to the CLK terminal in the release of pressing for the switch operation on the feed switch 61, and switches the control signal of the load switch 62, which is the output of the Q terminal, from the previous “L” to “H”.

The load switch 62 is closed upon receiving an input of the control signal of “H” from the D flip-flop 64 and generates a high voltage (V24V) on the output terminal side.

The DCDC converter 65 is supplied with the high voltage (V24V) generated by the load switch 62 and generates a voltage of 5 V. The voltage generated by the DCDC converter 65 is input to the Vin terminal of the power supply management IC 66 as an operation voltage.

In ACT12, the power supply management IC 66 receives the input of the operation voltage (Vin) to the Vin terminal, starts the sequence control of power supply startup, and outputs a plurality of low voltages (Vout1, Vout2, . . . , VoutN) at respective timings. Specifically, as shown in FIG. 3, the power supply management IC 66 switches the outputs of the plurality of low voltages (Vout1, Vout2, . . . , VoutN) from “L” to “H” at the respective timings.

Subsequently, the power supply management circuit 21 enters a state of waiting for the turn-off of the main power supply of the printer 10, and now waits for the execution of the long pressing of the feed switch 61 to turn off the main power supply. The long pressing includes the continuation of the pressing for a predetermined time or more. In ACT13, the power supply management circuit 21 waits for the pressing of the feed switch 61 for turning on the main power supply. Specifically, the power supply management IC 66 waits for the input of a switch signal of “L” to the power-on key terminal.

Until the feed switch 61 is pressed (during No in ACT13), the power supply management circuit 21 continues to wait for pressing of the feed switch 61.

When the feed switch 61 is pressed (Yes in ACT13), in ACT14, upon reception of an input of the switch signal of “L” to the power-on key terminal, the power supply management IC 66 starts measuring the duration of the input of “L” to the power-on key terminal, that is, the duration of the pressing of the feed switch 61. In addition, upon reception of an input of the switch signal of “L” to the A port, the CPU 67 starts measuring the duration of the input of “L” to the A port, that is, the duration of the pressing of the feed switch 61.

Subsequently, in ACT15, the power supply management IC 66 determines whether the duration of the pressing of the feed switch 61 has reached a predetermined time, that is, reached a predetermined time or more.

If the duration of the pressing of the feed switch 61 has not reached a predetermined time (No in ACT15), this is the situation in which the pressing of the feed switch 61 is released before the predetermined time elapses. The power supply management IC 66 then determines that the long pressing of the feed switch 61 has not been executed, and terminates the measurement of the duration of the pressing of the feed switch 61. The power supply management IC 66 returns to the processing of ACT13, and again waits for the pressing of the feed switch 61 to turn on the main power supply, that is, waits for an input of the switch signal of “L” to the power-on key terminal. In addition, the CPU 67 also terminates the measurement of the duration of the pressing of the feed switch 61.

If the duration of the pressing of the feed switch 61 has reached the predetermined time (Yes in ACT15), the power supply management IC 66 determines that the feed switch 61 has been long-pressed, and in ACT16, starts the sequence control of power supply shutdown to stop the plurality of low voltages (Vout1, Vout2, . . . , VoutN) at respective timings. Specifically, as shown in FIG. 3, the power supply management IC 66 switches the outputs of the plurality of low voltages (Vout1, Vout2, . . . , VoutN) from “H” to “L” in reverse order from the startup.

When the pressing of the feed switch 61 is released and the switch signal input to the A port of the CPU 67 is switched from “H” to “L”, the CPU 67 terminates the measurement of the duration of the pressing of the feed switch 61. If the duration of the pressing of the feed switch 61 is equal to or more than the predetermined time (which applies to the flowchart of FIG. 2), in ACT17, the CPU 67 temporarily outputs the clear signal of “L” to the D flip-flop 64 and clears the D flip-flop 64. Specifically, as shown in FIG. 3, the CPU 67 temporarily switches the clear signal, which is output from the B port to the clear terminal of the D flip-flop 64, from “H” to “L”, and then returns the clear signal to “H” again.

For example, the CPU 67 temporarily outputs the clear signal after the completion of the sequence control of power supply shutdown performed by the power supply management IC 66. In other words, the CPU 67 temporarily outputs the clear signal of “L” after the time, which is obtained by adding a time required for the sequence control of power supply shutdown to the predetermined time, has elapsed since the start of the input of the switch signal of “L”.

In other words, if the duration of the pressing of the feed switch 61 is equal to or more than the time obtained by adding a time required for the sequence control of power supply shutdown to the predetermined time, the CPU 67 temporarily outputs the clear signal of “L”. If the duration of the pressing of the feed switch 61 is less than the time obtained by adding a time required for the sequence control of power supply shutdown to the predetermined time, the CPU 67 temporarily outputs the clear signal of “L” after the shortage time has elapsed.

Instead of the CPU 67 clearing the D flip-flop 64 on the basis of the measurement of the duration of the pressing of the feed switch 61, the power supply management IC 66 may notify the CPU 67 of the completion of the sequence control of power supply shutdown when the sequence control of power supply shutdown is completed, and the CPU 67 may temporarily output the clear signal of “L” to clear the D-type flip-flop 64 upon receiving the notification on the completion of the sequence control of power supply shutdown.

The D flip-flop 64 receives the clear signal of “L” in the clear terminal and switches the control signal of the load switch 62, which is the output of the Q terminal, from the previous “H” to “L” as shown in FIG. 3.

The load switch 62 enters an open state upon reception of the input of the control signal of “L” from the D flip-flop 64 and stops generating a high voltage (V24V) on the output terminal side. Specifically, the voltage (V24V) on the output terminal side of the load switch 62 is switched from “H” to “L” as shown in FIG. 3.

The DCDC converter 65 stops generating a voltage (V5V) of 5 V in response to the stop of the supply of the high voltage (V24V) from the load switch 62. Specifically, the output voltage (V5V) of the DCDC converter 65 is switched from “H” to “L” as shown in FIG. 3.

### (Effects)

As can be seen from above, in the power supply management circuit 21 according to the embodiment, when the feed switch 61 is switched, the D flip-flop 64 closes the load switch 62, and the power supply management IC 66 accordingly starts the sequence control of power supply startup. When the feed switch 61 is long-pressed, the power supply management IC 66 starts the sequence control of power supply shutdown, and the CPU 67 causes the D flip-flop 64 to output the control signal to open the load switch 62. According to the power supply management circuit 21, the feed switch 61, which has been used for the on/off control of the printer 10 so far, can be used for the on/off control of the power supply management IC 66. In other words, the power supply management circuit 21 can simply perform the on/off control of the printer 10 and the power supply management IC 66.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power supply management circuit of a printer, comprising:
a first switch configured to be switched by a user;
a second switch configured to generate a first voltage and stop generating the first voltage in accordance with opening/closing of the second switch;
a logic circuit configured to control the opening/closing of the second switch;
a power supply management integrated circuit configured to perform sequence control of power supply startup and power supply shutdown; and
a control circuit configured to control an output of the logic circuit, wherein
when the first switch is switched, the logic circuit closes the second switch, and the power supply management integrated circuit starts the sequence control of power supply startup in accordance with the closing of the second switch, and
when the first switch is long-pressed, the power supply management integrated circuit starts the sequence control of power supply shutdown, and the control circuit causes the logic circuit to output a control signal to open the second switch.

2. The power supply management circuit according to claim 1, further comprising
a DCDC converter configured to step down the first voltage generated by the second switch and generate a second voltage, wherein
the power supply management integrated circuit is activated when the first switch is switched, and starts the sequence control of power supply startup upon receiving an input of the second voltage.

3. The power supply management circuit according to claim 1, wherein
when the first switch is long-pressed, the control circuit causes the logic circuit to output the control signal to open the second switch after completion of the sequence control of power supply shutdown by the power supply management integrated circuit.

4. The power supply management circuit according to claim 1, wherein
the first switch generates a switch signal of low level while the first switch is pressed, and generates a switch signal of high level while pressing of the first switch is released, and
the logic circuit is a D flip-flop that includes a D terminal that constantly receives an input of high level, a CLK terminal that receives an input of the switch signal, a clear terminal that receives an input of a clear signal from the control circuit, and a Q terminal that outputs a control signal for the second switch.

5. The power supply management circuit according to claim 1, wherein
the first switch generates a switch signal of low level while the first switch is pressed, and generates a switch signal of high level while pressing of the first switch is released, and
the logic circuit is a D flip-flop that
includes a D terminal that constantly receives an input of high level, a CLK terminal that receives an input of the switch signal, a clear terminal that receives an input of a clear signal from the control circuit, and a Q terminal that outputs a control signal for the second switch, and
holds the input of high level to the D terminal at a timing at which the input to the CLK terminal is switched from low level to high level to output the input of high level from the Q terminal, and outputs an input of low level from the Q terminal while the clear terminal receives the input of low level, and
the second switch is closed while receiving an input of the control signal of “H”, and is opened while receiving an input of the control signal of “L”.

6. The power supply management circuit according to claim 1, wherein
the first switch generates a switch signal of low level while the first switch is pressed, and generates a switch signal of high level while pressing of the first switch is released, and
the logic circuit is a D flip-flop that
includes a D terminal that constantly receives an input of high level, a CLK terminal that receives an input of the switch signal, a clear terminal that receives an input of a clear signal from the control circuit, and a Q terminal that outputs a control signal for the second switch, and
holds the input of high level to the D terminal at a timing at which the input to the CLK terminal is switched from low level to high level to output the input of high level from the Q terminal, and outputs an input of low level from the Q terminal while the clear terminal receives the input of low level,
the second switch is closed while receiving an input of the control signal of “H”, and is opened while receiving an input of the control signal of “L”, and
the power supply management integrated circuit
includes a Vin terminal that receives an input of an operation voltage, and a power-on key terminal that receives an input of the switch signal, and
enters a startup state when the power-on key terminal receives an input of high level, and starts the sequence control of power supply startup when the Vin terminal receives the input of the operation voltage.

7. The power supply management circuit according to claim 6, wherein
the power supply management integrated circuit starts measuring a duration of an input of the switch signal of low level when the power-on key terminal receives the input of the switch signal of low level, and starts the sequence control of power supply shutdown when the duration reaches a predetermined time.

8. The power supply management circuit according to claim 6, wherein
the power supply management integrated circuit starts measuring a duration of an input of the switch signal of low level when the power-on key terminal receives the input of the switch signal of low level, and starts the sequence control of power supply shutdown when the duration reaches a predetermined time, and
the control circuit starts measuring a duration of an input of the switch signal of low level when the input of the switch signal of low level is received, terminates the measurement of the duration when an input of the switch signal of high level is received, and temporarily outputs the clear signal of low level to the clear terminal of the logic circuit if the duration is equal to or more than a predetermined time.

9. The power supply management circuit according to claim 6, wherein
the power supply management integrated circuit starts measuring a duration of an input of the switch signal of low level when the power-on key terminal receives the input of the switch signal of low level, and starts the sequence control of power supply shutdown when the duration reaches a predetermined time,
the control circuit starts measuring a duration of an input of the switch signal of low level when the input of the switch signal of low level is received, terminates the measurement of the duration when an input of the switch signal of high level is received, and temporarily outputs the clear signal of low level to the clear terminal of the logic circuit if the duration is equal to or more than a predetermined time, and
the logic circuit outputs the control signal of low level from the Q terminal upon receiving an input of the clear signal of low level.

10. The power supply management circuit according to claim 6, wherein
the power supply management integrated circuit starts measuring a duration of an input of the switch signal of low level when the power-on key terminal receives the input of the switch signal of low level, and starts the sequence control of power supply shutdown when the duration reaches a predetermined time,
the control circuit starts measuring a duration of an input of the switch signal of low level when the input of the switch signal of low level is received, terminates the measurement of the duration when an input of the switch signal of high level is received, and temporarily outputs the clear signal of low level to the clear terminal of the logic circuit if the duration is equal to or more than a predetermined time,
the logic circuit outputs the control signal of low level from the Q terminal upon receiving an input of the clear signal of low level, and
the second switch enters an open state upon receiving an input of the control signal of low level, and stops generating the first voltage.
